(19) United States
(12) Patent Application Publication
(10) Pub. No.: US 2012/0049855 A1
(43) Pub. Date: Mar. 1, 2012

(54) Dark IV monitoring system for photovoltaic installations

(76) Inventor: David E. Crites, Los Gatos, CA (US)

(21) Appl. No.: 12/862,742

(22) Filed: Aug. 24, 2010

(51) Int. Cl. G01R 31/02

(52) U.S. Cl. 324/537

(57) ABSTRACT

A photovoltaic (PV) monitoring system performs dark current and dark IV testing of PV installations; computes the passive electrical characteristics of the installed array; determines the performance status and likely cause of underperformance; and communicates the collected data.

### CROSS-REFERENCE TO RELATED APPLICATIONS

N/A

### STATEMENT REGARDING FEDERALLY SPONSORED RESEARCH OR DEVELOPMENT

N/A

### REFERENCE TO SEQUENCE LISTING, A TABLE, OR A COMPUTER PROGRAM LISTING COMPACT DISC APPENDIX

N/A

### FIELD OF THE INVENTION

The invention is a system that tests and monitors PV installations. An electronic data acquisition system acquires dark current and voltage readings from PV modules and strings in order to assess their passive electrical characteristics, and uses a pattern recognition method to determine the likely cause of underperforming PV installations.

### BACKGROUND OF THE INVENTION

The output of a PV solar installation depends upon maintaining the health and performance of the PV modules that comprise the installation.

A number of factors affect the performance of PV modules. Such factors include infiltration, soiling, shading, ionizing radiation, interconnect integrity, electrostatic discharge, temperature stress, coating degradation, and manufacturing variation.

PV installation monitoring provides information about the performance and health of the installation and thus supports its maintenance and repair. Conventional methods that monitor the active output current of a PV string or array provide useful information about the performance of the string or array but may not provide the diagnostic information necessary to determine the cause of the underperformance, the identity of the affected modules, or the health of the bypass diodes that protect the string from hot-spot heating.

By monitoring the dark IV signature of a PV module or string the invention provides important diagnostic information about the cause of an underperforming module or string and the status of the module's or string's protective bypass diodes. For example, determining the passive characteristics of a PV string can distinguish between a string that is underperforming due to illumination issues such as shading, coating degradation, or soiling and a string that is underperforming due to electrical issues such as infiltration, interconnect degradation, or temperature stress. Dark IV testing may also allow characterization of bypass diodes.

### BRIEF DESCRIPTION OF THE DRAWINGS

FIG. 1 illustrates a first embodiment of a PV circuit monitoring unit of the invention.

FIG. 2 illustrates a second embodiment of a PV circuit monitoring unit of the invention.

FIG. 3 illustrates an embodiment of a PV multi-circuit monitoring unit of the invention.

FIG. 4 illustrates an embodiment of a PV combiner monitoring unit of the invention.

FIG. 5 illustrates a first embodiment of the stimulus circuit of FIGS. 1-3.

FIG. 6 illustrates a second embodiment of the stimulus circuit of FIGS. 1-3.

FIG. 7 illustrates a first embodiment of a PV series monitoring unit of the invention incorporated into a PV module.

FIG. 8 illustrates a second embodiment of a PV series monitoring unit of the invention.

FIG. 9 illustrates an embodiment of a PV parallel monitoring unit of the invention incorporated into a PV module.

FIG. 10 illustrates a representative PV installation incorporating a circuit monitoring unit of the invention.

FIG. 11 illustrates a representative PV installation incorporating one circuit monitoring unit of the invention, and a series monitoring unit of the invention incorporated into each PV module.

FIG. 12 illustrates a representative PV installation incorporating one circuit monitoring unit and multiple series monitoring units of the invention.

FIG. 13 illustrates a representative PV installation incorporating one circuit monitoring unit and two combiner monitoring units of the invention.

FIG. 14 illustrates a representative PV installation incorporating one circuit monitoring unit, two combiner monitoring units, and multiple series monitoring units of the invention.

FIG. 15 illustrates a representative PV installation incorporating one multi-circuit monitoring unit and multiple series monitoring units of the invention.

FIG. 16 illustrates a representative PV installation incorporating a circuit monitoring unit and two parallel monitoring units of the invention incorporated into PV-AC modules.

FIG. 17 illustrates a representative dark IV signature and the circuit model of a representative PV module.

### SUMMARY OF THE INVENTION

It is the object of the invention to provide a system, comprised of one or more units, capable of monitoring PV installations using dark current or dark IV testing. Dark current testing applies an electrical stimulus across parallel strings or modules and records their relative currents in order to compute their relative passive electrical characteristics. Dark IV testing applies a measured electrical stimulus across one or more PV modules and measures the circuit response in order to compute the absolute passive electrical characteristics of the tested module(s).

It is yet another object of the invention to provide an optional means and method to alter the circuit topology of the installed PV modules during testing in order to identify which modules or bypass diodes may be underperforming.

It is yet another object of the invention to provide a method for determining the health of a PV installation by measuring the dark current and dark IV signatures of one or more modules.

### DETAILED DESCRIPTION

The monitoring system of the invention may be comprised of one or more in-situ monitoring units of the invention and, optionally, the networking and computing resources common in the art.

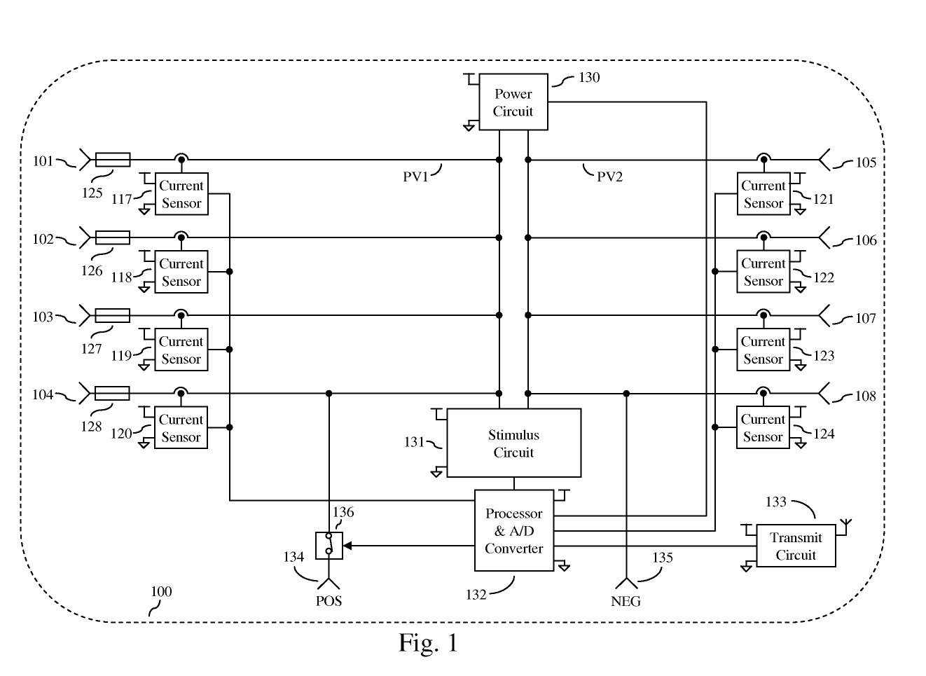

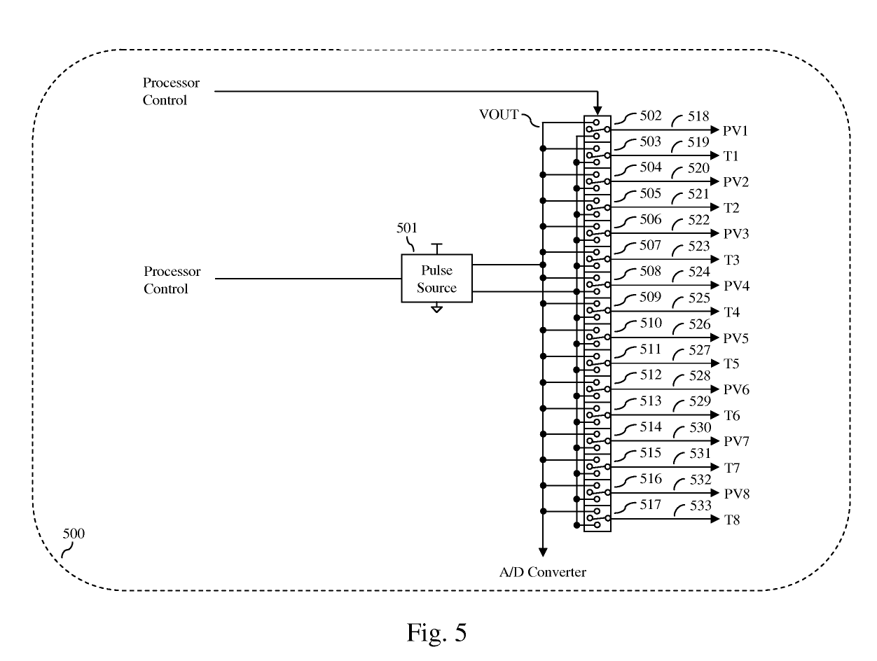

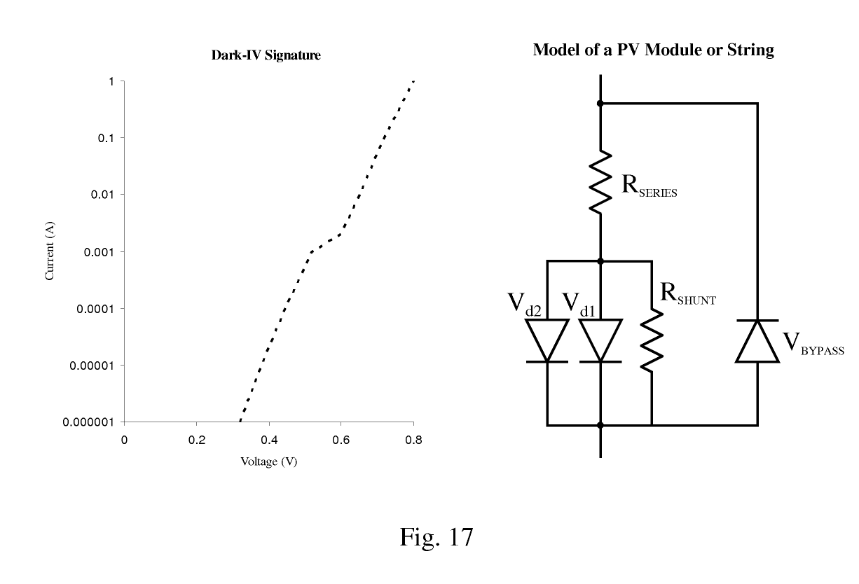

The circuit monitoring unit embodied in FIG. 1 consolidates PV current at both ends of a PV circuit. For convenience of illustration, FIG. 1 consolidates the positive (101-104) and negative (105-108) ends of four PV strings, but the number of connectors in FIG. 1 can be altered to accommodate installations with fewer or more PV strings. Connectors 134 and 135 pass PV generated current (POS and NEG) to external power components common in the art, such as a battery or inverter, and the processor-controlled switch (136) can be used to isolate the circuit monitoring unit from these external power components during passive testing of the array. The current sensors (117-124) may be enabled and polled by the processor (132), as necessary, to measure the currents flowing in and out of the circuit monitoring unit. Note that in some configurations, some of these current sensors (117-124) may be redundant and may be eliminated because they measure currents that are measured by other sensors. When enabled, the current sensors (117-124) convert measured currents to digital data and forward the data to the processor (132) for storage, analysis, and transmission (133) to other devices. Fuses (125-128) provide protection from string faults. The power circuit (130) provides electrical energy and management functions common in the art that may include, but are not limited to, mains power, battery power, power conversion, sleep management, electrical isolation, voltage regulation, and battery charging. In this embodiment, the stimulus circuit (131) provides both a means to communicate with series or parallel monitoring units (e.g. 500 in FIG. 5) in order to alter the topology of the test circuit, and a means to apply an electrical stimulus across one or more PV modules in order to measure the passive electrical characteristics of the tested module(s). In this embodiment, the stimulus circuit (131) performs a dark current test by applying a stimulus across the circuit that normally carries PV generated current, while the current through each string is sampled contemporaneously. The stimulus may include pulsed current, AC current, multiple DC currents, varied DC current, pulsed DC current, or any electrical stimulus capable of driving on or more current values through the modules being tested. In such a test, the percentage of current that flows through each string indicates the relative resistivity of each string. In a dark IV test the processor (132) collects both voltage and current samples in order to compute absolute resistive values and diode parameters for each module or string. These absolute values are computed from a dark IV signature (FIG. 17) and may be used to identify strings that are underperforming due to electrical issues, and distinguish them from strings that are underperforming due to illumination issues. When dark current is driven in the direction opposite the normal photovoltaic current, the attached PV modules will be forward-bias if the applied voltage exceeds the on-voltage (V_{d1} or V_{d2} in FIG. 17) of the entire string. When the tested modules are forward biased, the voltages and currents through each string may be used to characterize the “on” signature of each PV string. When dark current is driven in the same direction as normal photovoltaic current, the bypass diodes will be forward biased if the applied voltage exceeds the on-voltage (V_{BYPASS} in FIG. 17) of the entire bypass string. When the bypass diodes are forward biased, the voltages and currents through each string may be used to compute the “on” signature of each bypass string. At lower voltages the PV and bypass diodes turn off and the “off” signature of the attached strings can be computed from the measured voltages and currents through each parallel string. A curve fitting algorithm, common in the art, may then be used to perform a non-linear parameter estimation to determine the shunt and series resistance, the diode saturation currents, and the non-ideal diode factor (FIG. 17) of the monitored modules. FIG. 17 offers one model of a PV module or string. Other equivalent electrical models will yield a different, but similarly useful, set of parameters that may be computed based on the passive response of a PV module or string.

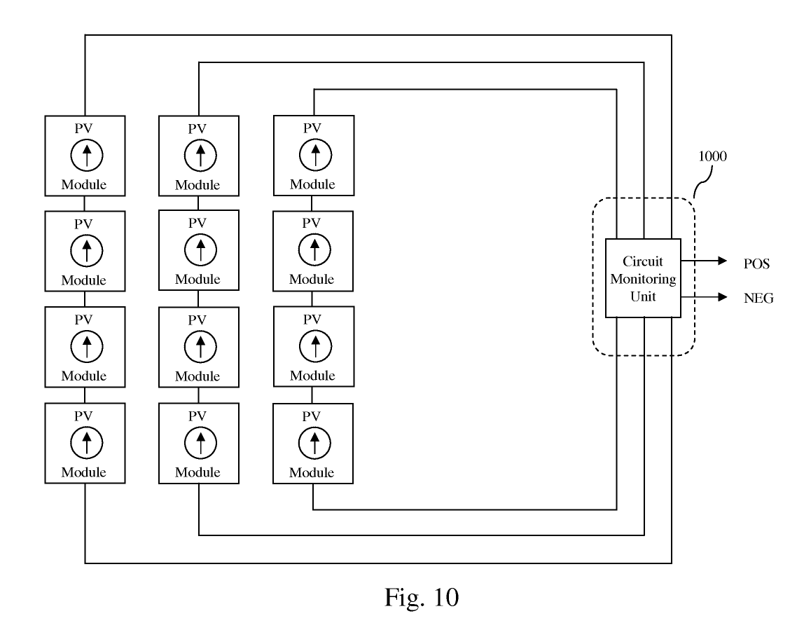

The circuit monitoring unit embodied in FIG. 1 may be used in a variety of PV array configurations. FIG. 10 illustrates an array configuration where the FIG. 1 circuit monitoring unit (100) is represented in-context as component 1000. In this configuration, PV connectors 101-103 consolidate positive current from parallel strings of PV modules, and PV connectors 105-107 consolidate negative current from the opposite ends of the same parallel strings. The circuit monitoring unit in FIG. 10 performs dark current and dark IV tests by driving current through the array wiring that normally carries PV-generated current. In a dark current test the processor collects contemporaneous current values from each current sensor and looks for outlying values. In a dark IV test the processor contemporaneously records voltage and current pairs from the parallel strings and can thus compute absolute resistance values and diode parameters for each string.

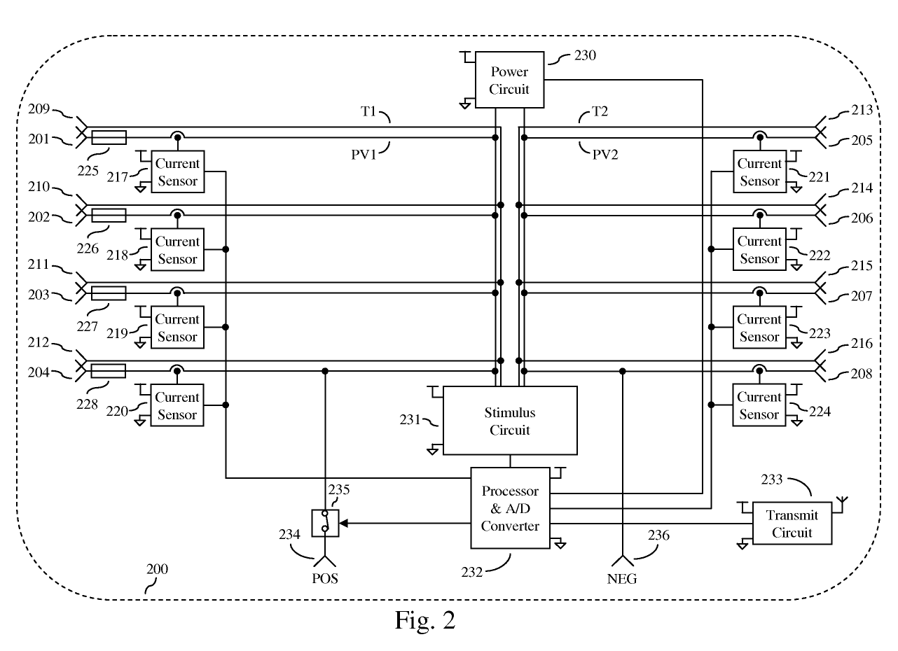

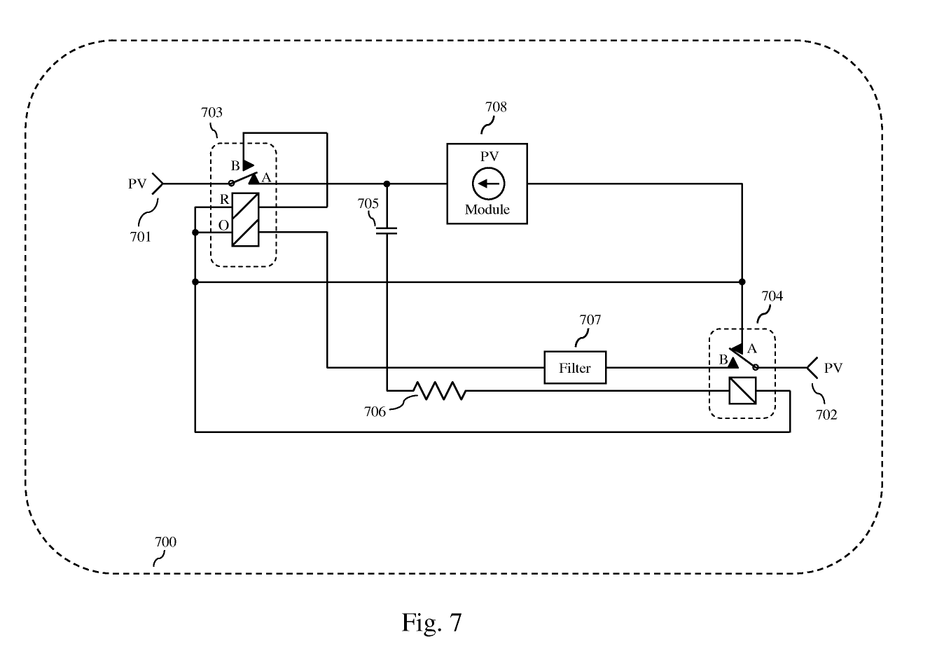

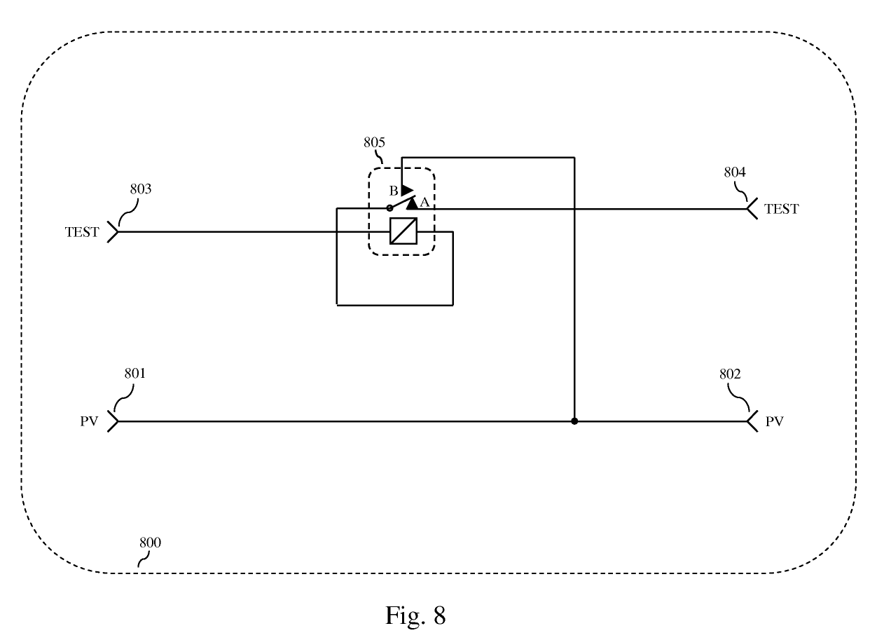

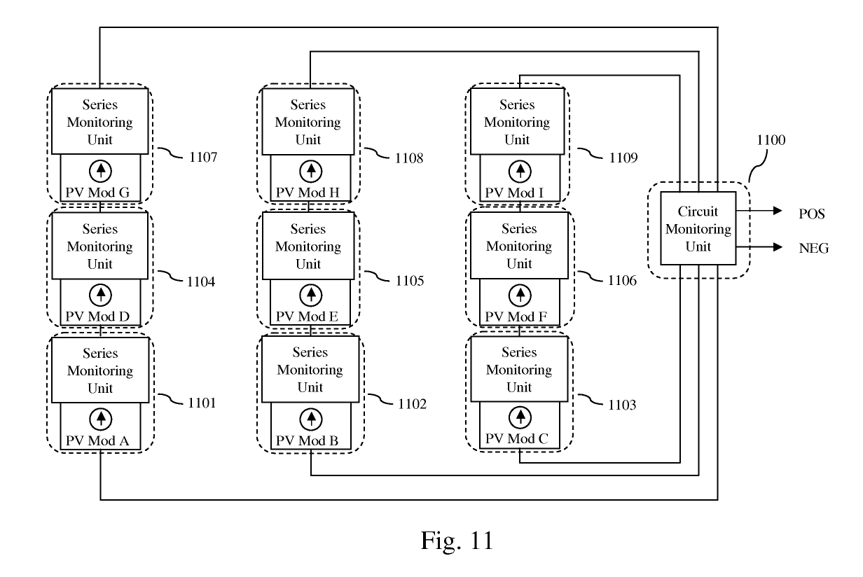

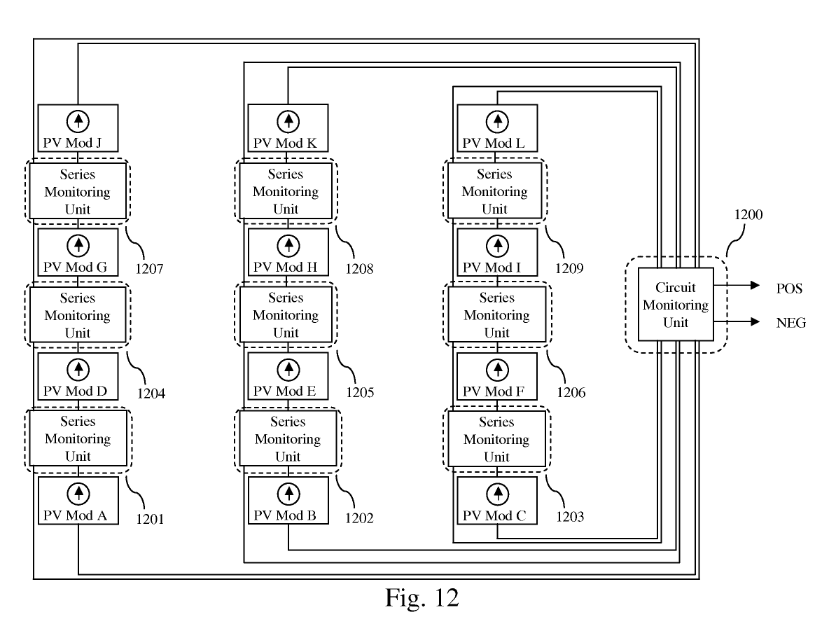

In the circuit monitoring unit embodied in FIG. 2, each positive connector (201-204) and negative connector (205-208) is paired with a test connector (209-216). Connectors 201-204 consolidate positive current from parallel strings of PV modules, connectors 205-208 consolidate negative current from the opposite ends of the same strings, and test connectors 209-216 are an optional test harness for series or parallel monitoring units wired into the PV. Some series or parallel monitoring unit embodiments may call for single-conductor wiring (e.g. FIG. 7 and FIG. 11) in which case the unused test connectors may be eliminated. Other series or parallel monitoring unit embodiments, may call for multi-conductor wiring (e.g. FIG. 8 and FIGS. 12, 14-15) in which case the number of test connectors is dictated by the requirements of the additional monitoring units. For ease of illustration, FIG. 2 illustrates one test conductor per PV conductor, but other ratios may be used. In FIG. 2, the test connectors (209-216) may be used to communicate with multi-conductor series or parallel monitoring units in order to alter the circuit topology of the array modules and facilitate more granular testing. In this embodiment, the stimulus circuit (231) communicates with the series or parallel monitoring units that are wired into the array by applying signals across any pair of the wires T1 (209-212), T2 (213-216), PV1 (201-204), or PV2 (205-208). Communication signals may be used to open or close switches in the attached series or parallel monitoring units and thus alter the circuit topology of the attached PV strings. A measured stimulus may also be applied across any pair of the wires T1, T2, PV1, or PV2 in order to collect data about the passive characteristics of the attached strings. This process of altering the circuit topology, applying a measured stimulus, and collecting data may be repeated in order to solve for the passive characteristics of individual modules or groups of modules.

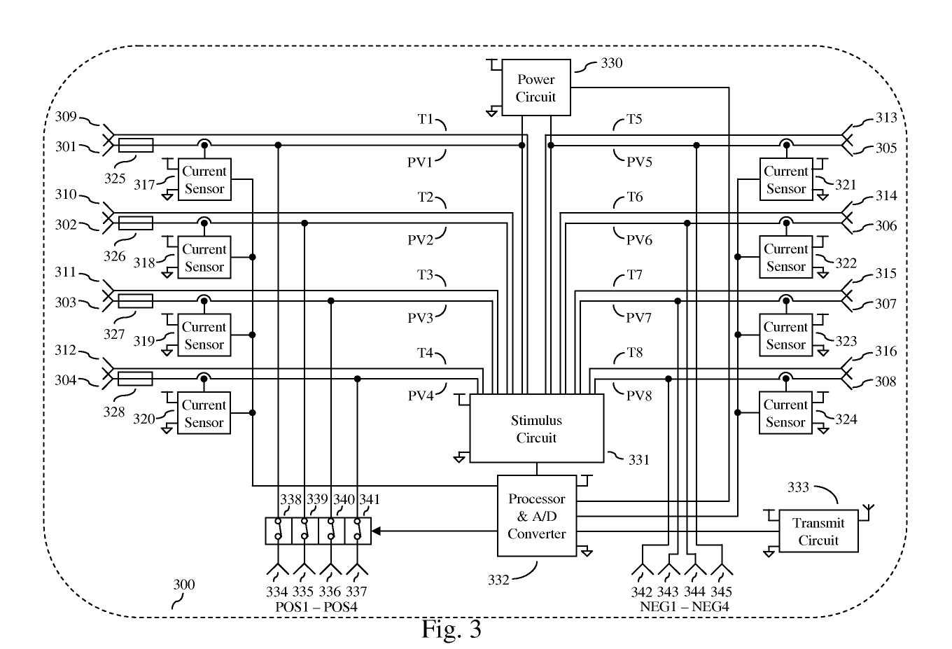

The multi-circuit monitoring unit embodied in FIG. 3 can be employed to monitor and test multiple PV circuits with one monitoring unit. For convenience of illustration, FIG. 3 shows a multi-circuit monitoring unit capable of monitoring four separate PV circuits, but any number may be supported. Connectors 334-337 and 342-345 pass generated PV current (POS1-POS4 and NEG1-NEG4) to external power components common in the art, such as a combiner box or maximum power point trackers. The processor-controlled switches (338-341) can be used to isolate the multi-circuit monitoring unit from these external power components during testing. Note that in FIG. 3 the current sensors (317-324) may be consolidated into one current sensor if it is moved into the stimulus circuit (331) to monitor VOUT (see FIG. 5).

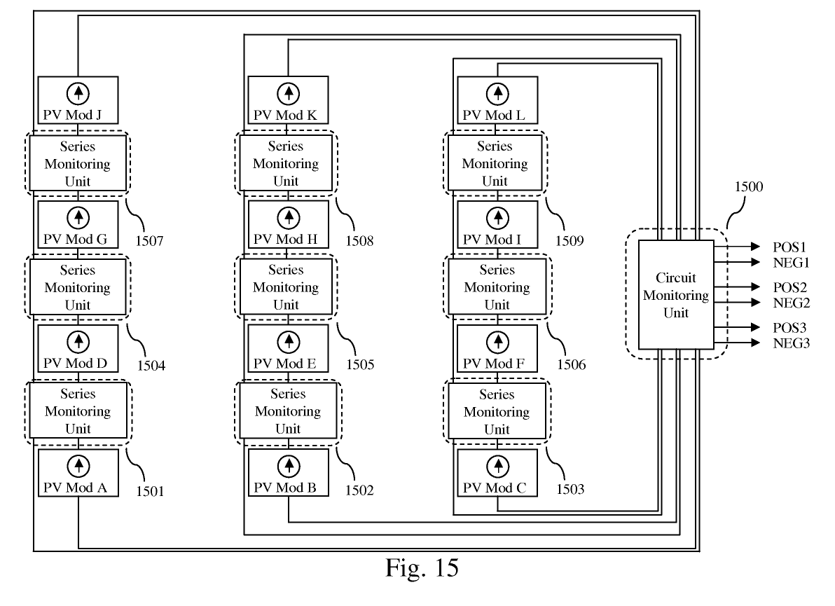

The multi-circuit monitoring unit embodied in FIG. 3 may be used in a variety of PV array configurations. FIG. 15 illustrates an array configuration where the FIG. 3 multi-circuit monitoring unit (300) is represented in-context as component 1500. In this configuration, connector 301 is wired to PV Module J; connector 302 is wired to PV Module K; connector 303 is wired to PV Module L; and connector 304 is unused. Likewise connector 305 is wired to PV Module A; connector 306 is wired to PV Module B; connector 307 is wired to PV Module C; and connector 308 is unused. In this configuration, each PV circuit is paired with one test circuit so connector 309 is wired to unit 1507, connector 310 is wired to unit 1508, connector 311 is wired to unit 1509, and connector 312 is unused. Similarly, connectors 313-315 are wired to units 1501-1503 respectively, and connector 316 is unused. The multi-circuit monitoring unit in FIG. 15 can perform dark IV tests on each PV circuit, either separately or in parallel, by controlling topology switches in the series monitoring units (if installed), driving measured current through the PV strings, and recording voltage and current pairs from each string. Dark current tests may be performed in parallel by controlling topology switches in the series or parallel monitoring units (if installed), driving current in parallel through the PV strings, collecting contemporaneous current values from each string, and looking for anomalies in the current ratios.

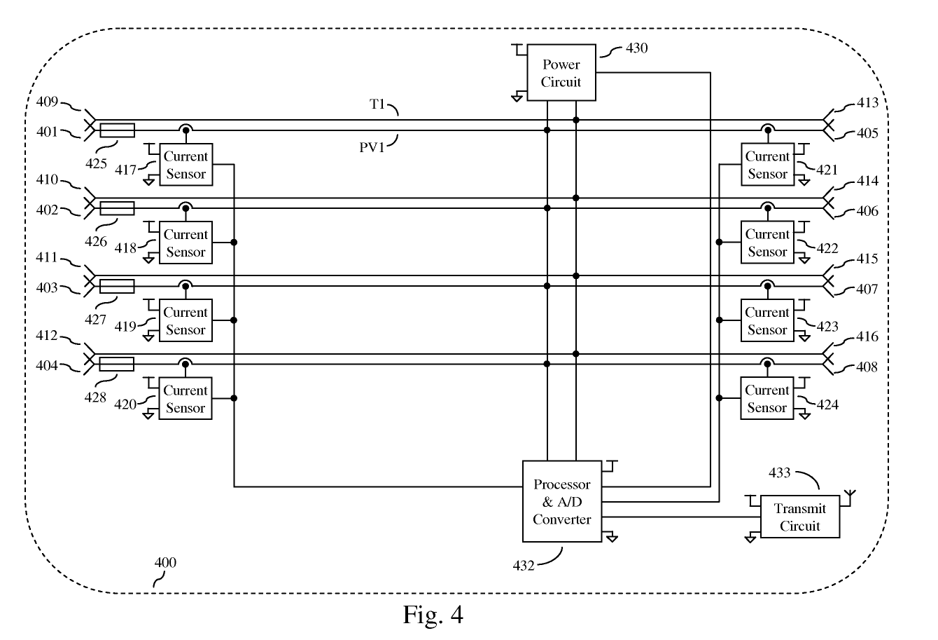

The combiner monitoring unit embodied in FIG. 4 consolidates PV current in the middle of a PV circuit when current consolidation is required by the topology of the PV installation. Note that the number of inputs and outputs in FIG. 4 can be altered to accommodate installations with fewer or more parallel strings. The power circuit (430) provides electrical energy and management functions common in the art that may include, but are not limited to mains power, battery power, power conversion, voltage regulation, sleep management, electrical isolation, and battery charging. In this embodiment, dark current tests are initiated by the array's circuit monitoring unit, during which the combiner monitoring unit's processor (432) enables the current sensors (417-424) to record contemporaneous current values from the parallel strings running in and out of the unit. Note that in some configurations, some of the current sensors (417-424) may be redundant and may be eliminated because they may measure currents that are measured by sensors in other units. When enabled, the current sensors (417-424) convert measured currents to digital data and forward the data to the processor (432) for storage, analysis, and transmission (433) to other devices. Dark IV tests are also initiated by the array's circuit monitoring unit, during which the combiner monitoring unit records voltage values (between PV1 and T1) concurrently with the current measurements.

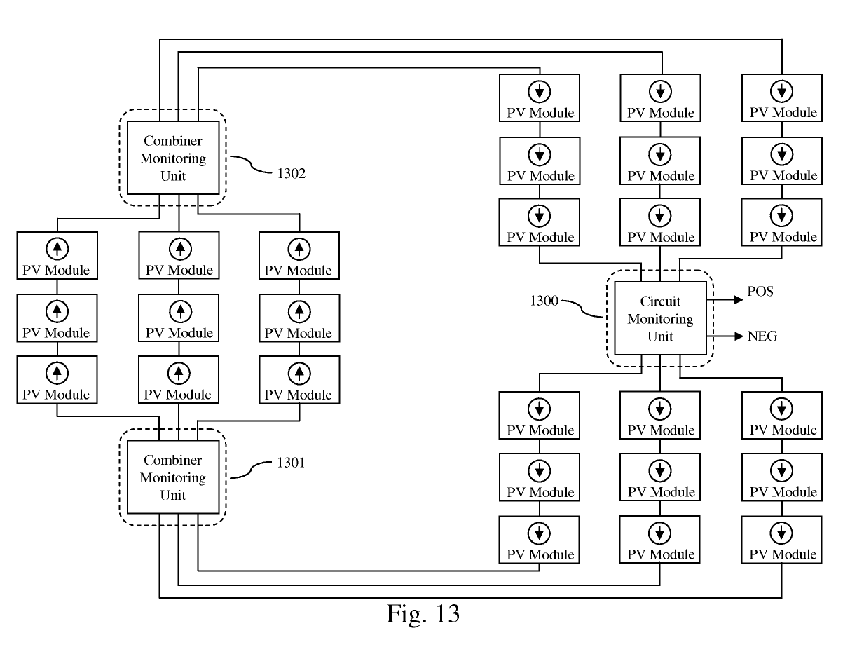

FIG. 13 illustrates an array configuration where the circuit monitoring unit of FIG. 1 (100) is represented in context as component 1300 and the combiner monitoring unit of FIG. 4 (400) is represented in context as components 1301 and 1302. This configuration is installed using single-conductor wiring so the test connectors (409-416) are unused and may be eliminated. In this configuration the circuit monitoring unit (100) initiates dark current tests by driving current through the array wiring that normally carries PV-generated current. During a dark current test, all three monitoring units (1300, 1301, and 1302) collect current data and look for outlying values in each concurrent set. Dark IV testing is not supported in this configuration because the combiner monitoring units have no reference voltage from which to make voltage measurements. Dark IV testing can be supported in this configuration if an additional wire is run from one of the test connectors (109-116) on the circuit monitoring unit (1300) to one of the test connectors (409-416) on both the combiner monitoring units (1301-1302), thus allowing the circuit monitoring unit to send a reference voltage (COMMON in FIG. 5) to the combiner monitoring units (T1 in FIG. 4).

FIG. 5 illustrates one embodiment of the stimulus circuit referenced in FIGS. 1-3. Signals T1-T8 and PV1-PV8 in FIG. 5 connect to the signals of the same names in each of the FIG. 1-3 alternative embodiments. For example, signal PV1 (518) in FIG. 5 ties to signal PV1 (101-104) in FIG. 1, or signal PV1 (201-204) in FIG. 2, or signal PV1 (301) in FIG. 3. For convenience of illustration, FIG. 5 illustrates a stimulus circuit with 16 switched (502-517) outputs (518-533) labeled PV1-PV8 and T1-T8 but any number of switched outputs can be used. Note that many of these switches and outputs are unused in FIGS. 1 and 2 and may be eliminated in those embodiments. The pulse source (501) produces a current pulse that may be used test the passive characteristics of the PV installation. Embodiments that support communication between monitoring units also produce a communication pulse that is electrically distinguishable from the test pulse. The output switches (502-517) are individually controlled by the processor and act as single-pole, triple-throw switches that can be tied to OPEN, COMMON, or VOUT.

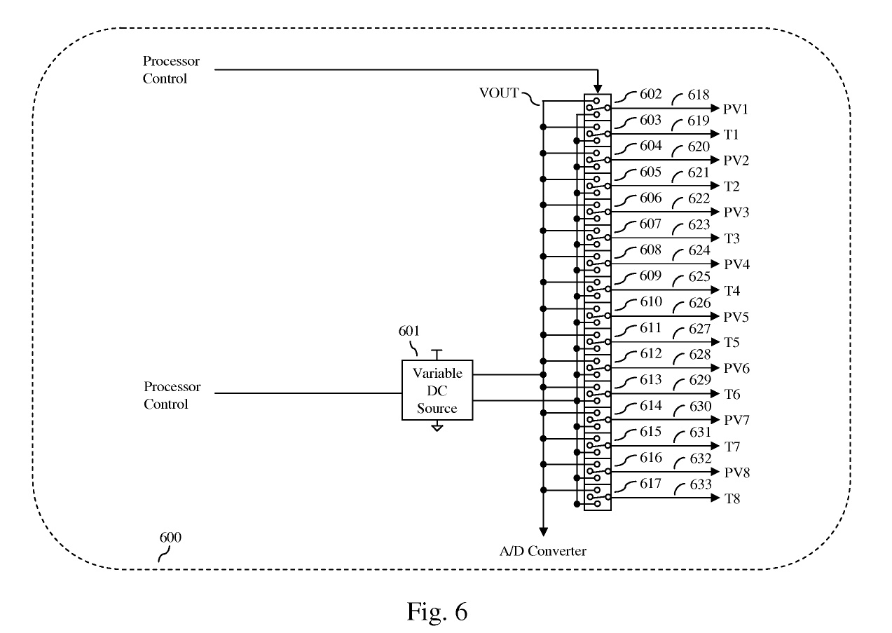

FIG. 6 illustrates an alternative embodiment of the stimulus circuit referenced in FIGS. 1-3. Signals T1-T8 and PV1-PV8 in FIG. 6 connect to the signals of the same names in each of the FIG. 1-3 alternative embodiments. For convenience of illustration, FIG. 6 illustrates a stimulus circuit with 16 switched (602-617) outputs (618-633) labeled PV1-PV8 and T1-T8 but any number of switched outputs can be used. Note that many of these switches and outputs are unused in FIGS. 1 and 2 and may be eliminated in those embodiments. The variable DC source (601) produces a range of direct current values that may be used to test the passive characteristics of the PV installation. Embodiments that support communication between monitoring units also produce a distinguishable direct current value for that purpose. The output switches (602-617) are individually controlled by the processor and act as single-pole, triple-throw switches that can be tied to OPEN, COMMON, or VOUT. A pulse source (501) may also be added to this embodiment in order to produce both DC and pulse stimuli if necessary.

The optional series monitoring unit (700) embodied in FIG. 7 may be incorporated into PV modules and installed using single conductor wiring. The series monitoring unit in FIG. 7 provides a means for the monitoring system to alter an array's circuit topology in order to assess the passive characteristics of individual modules. In FIG. 11 several PV modules with integrated series monitoring units (1101-1109) are illustrated in the context of a representative PV array. During normal operation of the PV array, each instance of the series monitoring unit (700) sits with the latching relays (703, 704) in position (A, A) so that generated PV current passes through connectors 701-702 and bypasses the filter (707). During normal DC operation of the PV array, capacitor 705, resistor 706, and relay 704 present a large shunt resistance across PV module 708. During darkness or twilight, a dark IV or dark current test of the entire circuit may be performed by the circuit monitoring unit while all the series monitoring units in the circuit are still in normal operating position (A, A). In such a test the circuit monitoring unit may apply a test stimulus across the PV circuit that normally carries generated current and the calculated parameters (or proportion of dark current flowing through each string) will reflect the health of each string. More detailed dark IV tests of the array may be performed by toggling the topology switches inside the series monitoring units. To toggle the series monitoring units, the circuit monitoring unit (e.g. FIG. 1) applies a pulse of changing current across PV1 (101-104) and PV2 (105-108), which connect through each series monitoring unit (701-702) and PV module (708) to create one or more closed circuits. This first communication pulse, in the direction opposite normal PV current, passes through capacitor 705 and toggles relay 704. So this first pulse of changing current sets every series monitoring unit in the array to position (A, B). DC test currents or pulses of slowly changing current applied at this stage measure the total passive characteristics of all the PV modules in the three strings of the array (e.g. A-I in FIG. 11). A second communication pulse in the direction opposite normal PV current toggles both relays in the first PV modules in each string (e.g. G-I in FIG. 11), but the filter (707) eliminates the pulse before it propagates to the next series monitoring units (e.g. D-F in FIG. 11). Therefore, this second communication pulse causes the other PV modules in the array (e.g. A-F in FIG. 11) to stay in position (A, B) while the first PV module in each string (e.g. G-I in FIG. 11) advances to position (B, A). DC or quasi-DC test currents applied at this stage measure the total passive characteristics of each PV string; minus its first PV module (e.g. G-I in FIG. 11). A third communication pulse in the direction opposite normal PV current toggles both relays in the second PV module in each string (e.g. D-F in FIG. 11), but the filter (707) eliminates the pulse before it propagates to the next series monitoring units (e.g. A-C in FIG. 11). Therefore, this third communication pulse causes the other PV modules in the array (e.g. A-C in FIG. 11) to stay in position (A, B) while the second PV module in each string (e.g. D-F in FIG. 11) advances to position (B, A). DC or quasi-DC test currents performed at this stage measure the total passive characteristics of each PV string; minus its first two PV modules (e.g. D-I in FIG. 11). This pattern of communication pulses and DC or quasi-DC tests may be repeated until testing is complete and one or more communication pulses in the direction of normal PV current returns the modules to their normal operating state by setting their relays (703, 704) back to position (A,A). Thus each reverse communication pulse causes the relays (703, 704) that receive it to cycle through the following positions: (A, A)→(A, B)→(B, A); and each forward communication pulse causes each relay 703 that receive it to release to its normal position A. In this embodiment, relay 703 is operated by coil O and released by coil R, and relay 704 is toggled (operated and released) by forward pulses through one coil. Note that both relays in this embodiment may require a time delay mechanism to ensure proper operation and release. In this embodiment, relays 703 and 704 are chosen so that their operating and release currents are higher than all test currents, and their operate and release times are consistent with the communication pulse being used. In this embodiment the filter (707) is chosen so that it filters communication pulses but not test stimuli. This series monitoring unit may also be implemented using other communication methods, test methods, switching methods, or switch types.

The alternative series monitoring unit (800) embodied in FIG. 8 may be connected in series with, or incorporated into, installed PV modules using two-conductor wiring. In FIG. 12 several series monitoring units (1201-1209) are illustrated in the context of a representative PV array. During normal operation of the PV array, each instance of the series monitoring unit (800) sits with the latching relay 805 in position A so that generated PV current passes through connectors 801 and 802. During darkness or twilight, a dark IV (or dark current) test of the entire circuit may be performed by a circuit monitoring unit while all the series monitoring units are still in position A. In such a test the circuit monitoring unit may apply a test stimulus across the PV circuit that normally carries generated current and the calculated parameters (or proportion of dark current flowing through each string) will reflect the health of each string. More detailed dark IV tests of the array may be performed by toggling the topology switch inside the series monitoring units. To toggle the series monitoring units, the circuit monitoring unit (e.g. FIG. 2) applies a high-current pulse across T1 (209-212) and T2 (213-216), which connect through each series monitoring unit (803-804) to create one or more closed circuits. This first high-current pulse sets relay 805 to position B in every series monitoring unit in the array. The circuit monitoring unit may now apply tests on the last module in each string (e.g. J-L in FIG. 12) by applying a lower-current test stimuli on T1 (209-212) and PV1 (201-204). Such tests may pass test currents through connectors 803 and 801 in the last circuit monitoring units in each string (1207-1209). Similarly, the circuit monitoring unit may also apply tests on the substrings comprised of all the modules except the last module in each string (e.g. A-I in FIG. 12) by applying a lower-current test stimulus on T1 (209-212) and PV2 (205-208). Such tests may pass test currents through connectors 803 and 802 in the last circuit monitoring units in each string (1207-1209). A second high-current pulse from the circuit monitoring unit, this time across T1 (209-212) and PV1 (201-204), may be used to reset relay 805 to position A in the last series monitoring units in the array (1207-1209). As a result, the circuit monitoring unit may now apply test currents across the last two modules of each string (e.g. G-L in FIG. 12) by applying a lower-current test stimulus on T1 (209-212) and PV1 (201-204). Such tests may pass test currents through connectors 803 and 801 in the next-to-last circuit monitoring unit of each string (1204-1206). Similarly, the circuit monitoring unit may also apply tests on the substrings comprised of all the modules except the last two modules in each string (e.g. A-F in FIG. 12) by applying a lower-current test stimulus on T1 (209-212) and PV2 (205-208). Such tests may pass test currents through connectors 803 and 802 in the next-to-last circuit monitoring unit of each string (1204-1206). This pattern of high-current communication pulses and lower-current test stimuli may be repeated until testing is complete and all the series monitoring units are returned to their normal operating state by setting their relay (805) to position A. The collected data may then be used to compute the passive characteristics of each module and their bypass diodes. Note that, in FIG. 12, one series monitoring unit is shown wired between each PV module, but the series monitoring units may actually be wired in other ratios, provided that no two series monitoring units are wired directly together. In this embodiment, relay 805 is operated by a current in one direction and released by a current in the opposite direction. The relay in this embodiment may require a time delay mechanism to ensure proper operation and release. In this embodiment, relay 805 is chosen so that the operating and release currents are higher than all test currents. This series monitoring unit may also be implemented using other switching schemes, other switch types, or powered logic.

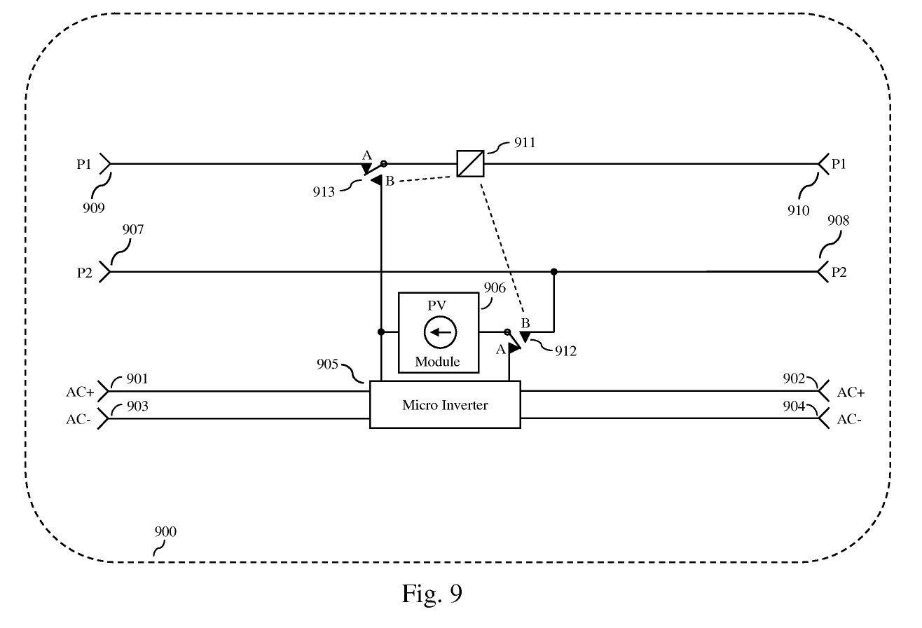

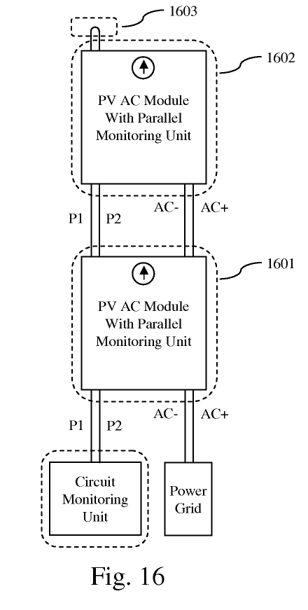

The parallel monitoring unit embodied in FIG. 9 isolates and collects data from PV modules or panels installed with micro-inverters. FIG. 16 illustrates the parallel monitoring unit (900) in the context of a representative PV array. During normal operation of the PV array, each instance of this parallel monitoring unit sits with armatures 912 and 913 in position A, and generated AC power passing through connectors 901-904. To use the parallel monitoring units, the circuit monitoring unit applies a high-current pulse across P1 and P2 (FIG. 16), which run in a circuit through each parallel monitoring unit (1601-1602) and through the loop-back fixture at the end of the array (1603). The high-current pulse energizes coil 911 in each parallel monitoring unit in the array. As a result, armatures 912 and 913 in each parallel monitoring unit will toggle to position B, isolating the PV modules from each other. Next, the circuit monitoring unit may apply a lower-current test stimulus in both directions across connectors 908 and 910 and the first module's (1601) passive characteristics may be recorded. The circuit monitoring unit may then apply a high-current pulse across connectors 908 and 910 to reset the armatures (912-913) in the first module (1601) back to position A. The circuit monitoring unit may then collect data from the next parallel monitoring unit (1602) by again applying a lower current stimulus in both directions across connectors 908 and 910. Testing may continue in this fashion until each module (or group of modules) has been tested and all the switches (912-913) in all of the parallel monitoring units are reset to position A. In this embodiment, relays 911-913 are chosen so that the operating and release currents are higher than all test currents.

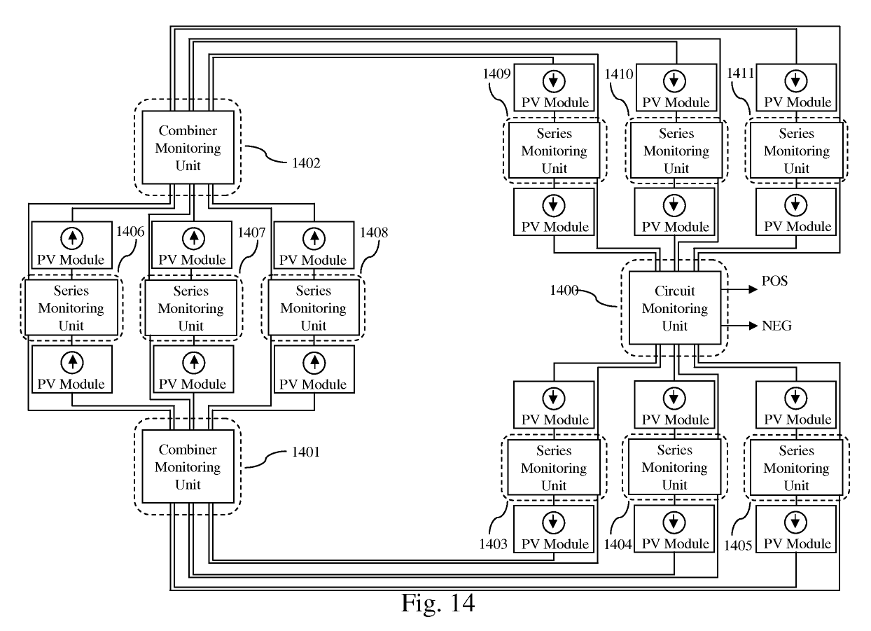

FIG. 14 illustrates an array configuration that incorporates one circuit monitoring unit (e.g. 200), represented in context as component 1400; two combiner monitoring units (e.g. 400), represented in context as components 1401-1402; and many series monitoring units (e.g. 800), represented in context as components 1403-1411. In this configuration, connectors 201-203 consolidate positive current from parallel strings of PV modules, connectors 205-207 consolidate negative current from the opposite ends of the same strings, and test connectors 209-211 and 213-215 connect to the series monitoring units (1403-1411) wired into the PV array. Even without using the series monitoring units, the strings in FIG. 14 may be tested by applying a test stimulus across both ends of the array and collecting current and voltage data for each string using all three monitoring units (1400-1402). The series monitoring units provide a means for altering the array's circuit topology in order to measure its passive characteristics at a more granular level. Note that, in FIG. 14, one series monitoring unit is shown wired in-between each PV module, but the series monitoring units may actually be wired in other ratios, provided that no two series monitoring units are wired directly together. The circuit monitoring unit may communicate with the series monitoring units by applying a communication signal across any pair of the wires T1, T2, PV1, or PV2. In the FIG. 2 embodiment, communication pulses are used to toggle switches in the series monitoring units in order to alter the circuit topology of the array. Then a measured stimulus across any pair of the wires T1, T2, PV1, or PV2 may be employed to collect data about the passive characteristics of that circuit topology. During dark IV tests, all three monitoring units collect both current and voltage samples in order to compute the passive characteristics of each test topology. This process of altering the circuit topology, applying a measured stimulus, and collecting data is repeated to solve for passive characteristics at a more granular level than string testing can provide on its own.

The data collected by the system may be used to determine the performance status of a PV installation and make maintenance recommendations. String-level dark current or dark IV tests early in the life of an installation set a baseline for the normal distribution of current between strings and, when within acceptable limits, indicates normal manufacturing, installation, and sampling variability. In new installations, significant imbalances indicate that installers may need to address a design, equipment, mounting or thermal issue. As the installation ages, resistance or relative currents may be compared over time to recognize unusual drops in one or more string currents. Such drops may indicate increased series resistance, such as corrosion, or decreased shunt resistance, such as metal migration, that may require replacement of one or more modules. When string-level operating currents are abnormal but string-level dark current or dark IV tests are normal, there is possibly a shading or soiling issue that needs to be addressed. If shading and soiling have been eliminated as potential issues, then coating or encapsulant degradation may be indicated. Anomalies in the passive models of PV modules may also be determined by comparing them to published specifications, idealized models, or other measured modules. Finer grained (i.e. module level) dark current or dark IV tests follow a similar diagnostic pattern but at a sub-string or module level. The passive parameters of an array, sub-array, string, or module collected by the monitoring system are made available for review by the array owners or operators. Automated flags are also set to report changes in the installation that are outside customizable thresholds.

In some embodiments, dark current and dark IV testing may not need to be performed during darkness or twilight. In such embodiments the operating voltage produced by the PV modules may be measured and used as a baseline to adjust the stimuli and measurements. Even when tests are performed during darkness, the night sky produces a small back-ground voltage, for which the system can compensate.

Switches in this invention may be implemented by a number of means including, but not limited to, electronic, electromechanical, electromagnetic, electro-acoustic or electro-optical switches common in the art.

The monitoring system may include lightning surge arrest protection.

Some components of the monitoring system may be implemented with electrical isolation from the PV power circuits.

The monitoring units of the invention may be integrated with other PV system components.

I do not wish to limit my invention to the examples and graphs described herein but rather to include such modifications as would be obvious to the ordinary worker skilled in the art of designing monitoring systems or measuring the parameters of photovoltaic modules.

The invention claimed is:

1. A system for the in-situ monitoring of the passive electrical parameters of one or more installed PV modules, the system comprising: the in-situ electrical wiring; a means for periodically applying through said wiring a non-PV electrical stimulus; and
a means for computing one or more passive electrical parameters of said modules.

2. The monitoring system of claim 1, wherein said stimulus is comprised of a plurality of current magnitudes.

3. The monitoring system of claim 1, wherein said parameters comprise resistance values.

4. The monitoring system of claim 1, further comprising a means for recognizing anomalies in said parameters.

5. The monitoring system of claim 4, further comprising a means for reporting said parameters and said anomalies.

6. The monitoring system of claim 1, further comprising a means for limiting said stimulus-applying to occur during periods of darkness or twilight.

7. The monitoring system of claim 1, wherein said stimulus-applying means is comprised of at least one DC source.

8. The monitoring system of claim 1, wherein said stimulus-applying means is comprised of at least one AC source.

9. The monitoring system of claim 1, further comprising a means for recording a plurality of current-voltage data points that measure the passive response of said modules to said stimulus.

10. The monitoring system of claim 9, wherein said recording means is comprised of at least one current sensor.

11. The monitoring system of claim 1, further comprising: a means for altering the circuit topology of said modules.

12. The monitoring system of claim 11, wherein said altering means is controlled, in whole or in part, by signals propagated through the PV cells and wires that carry PV generated current.

13. The monitoring system of claim 12, wherein said signals are produced by said stimulus-applying means.

14. The monitoring system of claim 11, wherein said altering means is comprised of one or more switches.

15. The monitoring system of claim 11, wherein said altering means is incorporated into a PV module comprising at least one photovoltaic cell.

16. The monitoring system of claim 1, wherein said stimulus-applying means is incorporated into a circuit combiner box, transformer box, disconnect box, charge controller box, fuse box, surge protection box, breaker box, inverter box, or other PV system component.

17. A method of determining the health of a PV installation, the method comprising the following steps in the order named: a) selecting a test period during darkness or twilight; b) applying an electrical test stimulus through one or more installed PV modules; d) computing one or more passive electrical parameters of said modules.

18. The method according to claim 17, wherein following the applying step and prior to the computing step is the step of: c) recording a plurality of current-voltage data points that measure the passive response of said modules to said stimulus.

19. The method according to claim 17, wherein said parameters comprise resistance values.

20. A method of altering the circuit topology of a PV installation comprising one or more installed PV modules, the method comprising the following steps in the order named: a) selecting a signaling period during darkness or twilight; b) signaling one or more switches in the PV installation to toggle.
